(19) United States
(12) Patent Application Publication
(10) Pub. No.: US 2024/0141485 A1
(43) Pub. Date: May 2, 2024

(54) VAPOR PHASE PRECURSOR DELIVERY SYSTEM

(71) Applicant: ASM IP Holding B.V., Almere (NL)

(72) Inventor: Theodorus G.M. Oosterlaken, Oudewater (NL)

(21) Appl. No.: 18/494,430

(22) Filed: Oct. 25, 2023

Related U.S. Application Data
(60) Provisional application No. 63/381,168, filed on Oct. 27, 2022.

(51) Int. Cl. C23C 16/448; C23C 16/08; C23C 16/455; C23C 16/52

(52) U.S. Cl. CPC C23C 16/448; C23C 16/08; C23C 16/45565; C23C 16/52

(57) ABSTRACT

A vapor phase precursor delivery system for delivering a vapor phase precursor for depositing a layer in a vapor phase deposition apparatus is disclosed. The vapor phase precursor delivery system having: a gas outlet; a gas inlet; a vessel constructed and arranged for storing a precursor; and a connecting tube contained within the vessel. The connecting tube may be connected to and in fluid communication with the gas inlet. A vapor phase deposition apparatus, such as for example a vertical furnace may have such a vapor phase precursor delivery system for depositing a layer on a substrate.

### CROSS-REFERENCE TO RELATED APPLICATION(S)

This application claims the benefit of U.S. Provisional Application 63/381,168 filed on Oct. 27, 2022, the entire contents of which are incorporated herein by reference.

### FIELD OF INVENTION

The disclosure generally relates to a vapor phase precursor delivery system for delivering a vapor phase precursor for depositing a layer in a vapor phase deposition apparatus. In particular, the disclosure relates to a vapor phase precursor delivery system comprising: a gas outlet; a gas inlet; a vessel constructed and arranged for storing a precursor; and, a connecting tube contained within the vessel, the connecting tube being connected to and in fluid communication with the gas inlet.

The disclosure further relates to a vapor phase deposition apparatus, such as for example a vertical furnace comprising such a vapor phase precursor delivery system for depositing a layer on a substrate.

### BACKGROUND OF THE DISCLOSURE

A vapor phase precursor delivery system for delivering a vapor phase precursor for depositing a layer on a substrate in a reactor of a vapor phase deposition apparatus may exhibit certain challenges. One of these challenges may be that the precursor delivery system may deliver to less vapor and the precursor delivery may in fact become a bottle neck for the productivity of the deposition apparatus. One of the reasons that the precursor delivery system may be delivering to less precursor is that the vapor pressure of the precursor may be very low. This may be especially the case with solid precursors.

Another bottle neck for the productivity of the vapor phase deposition apparatus system may be that the delivery of the precursor may be dependent on the level of the precursor in the vessel for storing the precursor. Since the level of the precursor in the vessel during use of the system may vary the quantity of the precursor vaporized in the system may also vary.

### SUMMARY OF THE DISCLOSURE

It may be an objective to provide a vapor phase precursor delivery system for delivering a vapor phase precursor. The precursor delivery of the system may be less sensitive to variations of the level of the precursor in the vessel.

Accordingly, there may be provided a vapor phase precursor delivery system comprising: a gas outlet; a gas inlet; a vessel constructed and arranged for storing a precursor; and a connecting tube contained within the vessel. The connecting tube may be connected to and in fluid communication with the gas inlet. The system may be provided with a moveable injector connected to and in fluid communication with the connecting tube and constructed and arranged for injecting gas from the gas inlet at a substantial constant level from the surface of the precursor in the vessel.

Also, a vapor phase deposition apparatus may be provided. The apparatus may comprise a vapor phase precursor delivery system for delivering a vapor phase precursor for depositing a layer on a substrate. The apparatus may be a vertical furnace comprising a reactor constructed and arranged to load a boat with a plurality of substrates. The vapor phase precursor delivery system may be constructed and arranged for delivering a vapor phase precursor for depositing a layer on the substrates in the reactor.

This summary is provided to introduce a selection of concepts in a simplified form. These concepts are described in further detail in the detailed description of example embodiments of the disclosure below. This summary is not intended to identify key features or essential features of the claimed subject matter, nor is it intended to be used to limit the scope of the claimed subject matter.

### BRIEF DESCRIPTION OF THE DRAWING FIGURES

FIGS. 1A and 1B disclose a vapor phase precursor delivery system according to the prior art.

FIGS. 2A and 2B discloses a vapor phase precursor delivery system according to an embodiment.

FIG. 3 disclose a vapor phase precursor delivery system according to a further embodiment for creating bubbles.

FIG. 4 discloses a vapor phase precursor delivery system 1 according to a further embodiment with a lifting device.

FIG. 5 discloses a vapor phase precursor delivery system 1 according to a further embodiment for a solid precursor.

It will be appreciated that elements in the FIGURES are illustrated for simplicity and clarity and have not necessarily been drawn to scale. For example, the dimensions of some of the elements in the FIGURES may be exaggerated relative to other elements to help improve understanding of illustrated embodiments of the present disclosure.

### DETAILED DESCRIPTION OF EXEMPLARY EMBODIMENTS

Although certain embodiments and examples are disclosed below, it will be understood by those in the art that the invention extends beyond the specifically disclosed embodiments and/or uses of the invention and obvious modifications and equivalents thereof. Thus, it is intended that the scope of the invention disclosed should not be limited by the particular disclosed embodiments described below

As used herein, the term “substrate” may refer to any underlying material or materials, including any underlying material or materials that may be modified, or upon which, a device, a circuit, or a film may be formed. The “substrate” may be continuous or non-continuous; rigid or flexible; solid or porous; and combinations thereof. The substrate may be in any form, such as a powder, a plate, or a workpiece. Substrates in the form of a plate may include wafers in various shapes and sizes. Substrates may be made from semiconductor materials, including, for example, silicon, silicon germanium, silicon oxide, gallium arsenide, gallium nitride and silicon carbide.

As examples, a substrate in the form of a powder may have applications for pharmaceutical manufacturing. A porous substrate may comprise polymers. Examples of workpieces may include medical devices (for example, stents and syringes), jewelry, tooling devices, components for battery manufacturing (for example, anodes, cathodes, or separators) or components of photovoltaic cells, etc.

A continuous substrate may extend beyond the bounds of a process chamber where a deposition process occurs. In some processes, the continuous substrate may move through the process chamber such that the process continues until the end of the substrate is reached. A continuous substrate may be supplied from a continuous substrate feeding system to allow for manufacture and output of the continuous substrate in any appropriate form.

Non-limiting examples of a continuous substrate may include a sheet, a non-woven film, a roll, a foil, a web, a flexible material, a bundle of continuous filaments or fibers (for example, ceramic fibers or polymer fibers). Continuous substrates may also comprise carriers or sheets upon which non-continuous substrates are mounted.

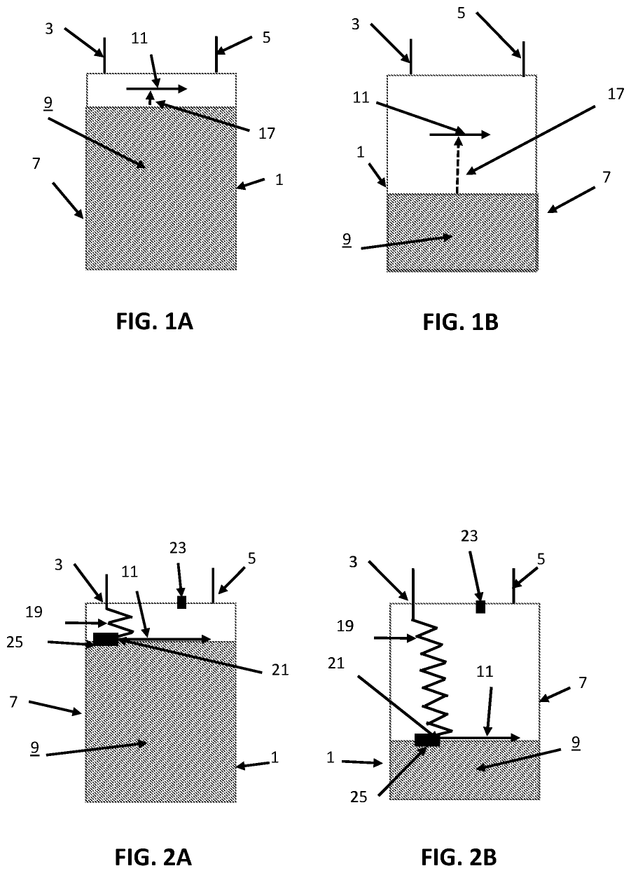

FIGS. 1A and 1B disclose a vapor phase precursor delivery system 1 comprising: a gas inlet 3 and a gas outlet 5. The vapor phase precursor delivery system 1 may comprise a vessel 7 constructed and arranged for storing a precursor 9. A gas flow 11 may be created between the gas inlet 3 and the gas outlet 5 for example with an inert gas like nitrogen within the vessel 7. The gas flow 11 may cause some precursor 9 to evaporate 17 into the gas flow 11 which may be transported out of the vessel 7 via the gas outlet 5. The evaporation of the precursor 9 may be dependent on the level of the precursor in the vessel 7 for storing the precursor. Since the level of the precursor 9 in the vessel 7 during use of the system 1 may be lowered from a relatively full vessel 7 in FIG. 1A to a relatively empty vessel 7 in FIG. 1B the quantity of the precursor 9 vaporized 17 in the system 1 may also be lower since the gas flow 11 is further away.

FIGS. 2A and 2B disclose a vapor phase precursor delivery system 1 according to an embodiment comprising a gas inlet 3 and a gas outlet 5. The vapor phase precursor delivery system 1 may comprise a vessel 7 constructed and arranged for storing a precursor 9. A connecting tube 19 may be provided in the vessel 7. The connecting tube 19 may be connected to and in fluid communication with the gas inlet 3. The system 1 may be provided with a moveable injector 21 connected to and in fluid communication with the connecting tube 19.

The moveable injector 21 may be constructed and arranged for injecting gas from the gas inlet 3 to create a gas flow 11. The moveable injector 21 may be constructed and arranged for injecting gas at a substantial constant level from a surface of the precursor 9 in the vessel 7 to create a gas flow 11 over the surface of the precursor 9. The level of the precursor 9 in the vessel 7 during use of the system 1 may be lowered from a relatively full vessel 7 in FIG. 2A to a relatively empty vessel 7 in FIG. 2B. The quantity of the precursor 9 vaporized 17 in the system however may be kept constant since the gas flow 11 is kept at a constant distance from the surface of the precursor 9. This is advantageous because the quantity of precursor in the gas flowing out of the gas outlet 5 remains constant as well.

The connecting tube 19 may be flexible and constructed and arranged to allow for movement of the injector 21 with respect to the gas inlet 3. For example, the connecting tube 19 may be made from flexible material e.g. rubber.

The vessel 7 may be constructed and arranged to hold a liquid precursor 9. The system 1 may be provided with a floating body 25 constructed and arranged for floating on the liquid precursor 9. The floating body 25 may be provided or integrated at the bottom of the injector 21. The floating body 25 may support the injector 21. The floating body and the injector may be constructed and arranged to provide a gas flow 11 over the surface of the precursor 9. The gas flow 11 may cause some precursor 9 to vaporize 17 into the gas flow 11 which may be transported out of the vessel 7 via the gas outlet 5.

The system 1 may be provided with a fill port provided with a lid 23 for filling the vessel 7 with precursor 9. Based upon the precursor the fill port and the lid 23 may be relatively bigger for solid precursor or relatively smaller for liquid precursor.

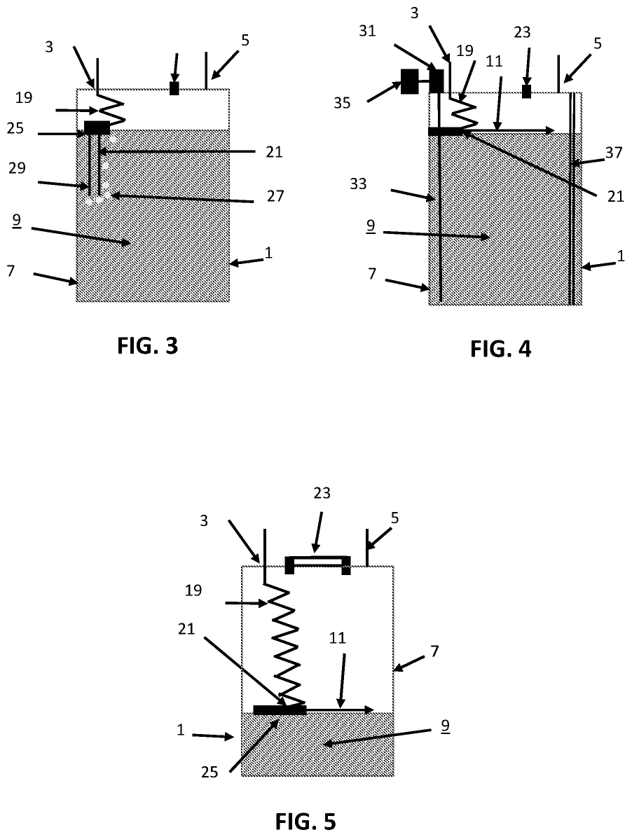

FIG. 3 discloses a vapor phase precursor delivery system 1 according to a further embodiment comprising a gas inlet 3 and a gas outlet 5. The vapor phase precursor delivery system 1 may comprise a vessel 7 constructed and arranged for storing a precursor 9. A connecting tube 19 may be provided in the vessel 7. The connecting tube 19 may be connected to and in fluid communication with the gas inlet 3. The system 1 may be provided with a moveable injector 21 connected to and in fluid communication with the connecting tube 19. The floating body 25 and the injector 21 of the system 1 may be constructed and arranges to provide a gas flow underneath the surface of the precursor 9. The floating body 25 and the injector 21 may be constructed and arranged to create bubbles 27 underneath the surface of the precursor 9. The bubbles 27 moving through the precursor 9 may cause some precursor 9 to vaporize into the bubbles 27, which may be transported out of the vessel 7 via the gas outlet 5.

The system 1 may be provided with multiple injectors for injecting gas from the gas inlet 3 at a substantial constant level from the surface of the precursor. The system 1 may, for example, be provided with an additional moveable injector 29 connected to and in fluid communication with the connecting tube 19. The injectors 21, 29 may be constructed and arranged as a showerhead provided with multiple holes for injecting gas from the holes at a substantial constant level from the surface of the precursor 9.

FIG. 4 discloses a vapor phase precursor delivery system 1 according to a further embodiment comprising a gas inlet 3 and a gas outlet 5. The vapor phase precursor delivery system 1 may comprise a vessel 7 constructed and arranged for storing a precursor 9. A connecting tube 19 may be provided in the vessel 7. The connecting tube 19 may be connected to and in fluid communication with the gas inlet 3. The system 1 may be provided with a moveable injector 21 connected to and in fluid communication with the connecting tube 19. 11. The system may be provided with a lifting device 31 constructed and arranged for moving and supporting the injector 21.

The lifting device 31 may have a linear drive for moving and supporting the injector 21. The linear drive may be for example a motor and a spindle 33 cooperating with a moving nut provided to the injector 21.

Alternatively, the spindle 33 and the nut of the lifting device 31 may be shielded off from the precursor 9 in the vessel 7 by a cover (not shown). The cover may circumvent contamination of the precursor 9 by wear or lubricants of the spindle 33 and nut and/or any linear guide used in the lifting device 31. The nut and the injector 21 may be mechanically and/or magnetically coupled to transfer the movement of the nut to the injector 21 through the cover.

The system 1 may be provided with a controller 35 to control the movement of the injector 21 by the lifting device 31. The system 1 may be provided with a level measurement device 37 to measure the level of the precursor 9. The controller 35 may be operably connected to the level measurement device 37 to control the movement of the injector 21 on the basis of the precursor level measured by the level measurement device 37. The controller 35 may be programmed to control the lifting device 31 to have the injector 21 to provide a gas flow over the surface of the precursor 9.

The controller 35 may be programmed to control the lifting device 31 to have the injector 21 to provide a gas flow underneath the surface of the precursor 9. The vessel 7 may be constructed and arranged to hold a liquid precursor 9 and the controller 35 may be programmed to control the lifting device 31 to have the injector 21 to create bubbles 27 underneath the surface of the precursor 9.

FIG. 5 discloses a vapor phase precursor delivery system 1 according to a further embodiment comprising a gas inlet 3 and a gas outlet 5. The vapor phase precursor delivery system 1 may comprise a vessel 7 constructed and arranged for storing a solid precursor 9. A connecting tube 19 may be provided in the vessel 7. The connecting tube 19 may be connected to and in fluid communication with the gas inlet 3. The system 1 may be provided with a moveable injector 21 connected to and in fluid communication with the connecting tube 19. The injector 21 may be constructed and arranged to be supported on the surface of the solid precursor 9 in the vessel 7. The system 1 may be constructed and arranged for the injector 21 to follow the surface of the solid precursor 9 when the solid precursor sublimates from the vessel 7.

The vessel 7 may be constructed and arranged to hold and sublimate a metal chloride. For example, the vessel may be constructed and arranged to hold and sublimate hafnium chloride or zirconium chloride as the metal chloride.

The system 1 may be provided with a fill port and a lid 23 to provide the solid precursor 9. The lid may be provided with the inlet port 3 and the outlet port 5. The lid may be provided with a grip for an operator.

The system 1 may be constructed and arranged to hold and vaporize a liquid with a relatively high viscosity compared to the viscosity of water.

The vapor phase precursor delivery system 1 may be used in a vapor phase deposition apparatus for delivering a vapor phase precursor for depositing a layer on a substrate. The vapor phase deposition apparatus may be a vertical furnace comprising a reactor constructed and arranged to load a boat with a plurality of substrates and the vapor phase precursor delivery system is constructed and arranged for delivering a vapor phase precursor for depositing a layer on the substrates in the reactor. A vertical furnace suitable to use the vapor phase precursor delivery system 1 may be described in U.S. Pat. No. 7,732,350 B2 for example incorporated herein by reference.

The illustrations presented herein are not meant to be actual views of any particular material, structure, or device, but are merely idealized representations that are used to describe embodiments of the disclosure.

The implementations shown and described are illustrative of the invention and its best mode and are not intended to otherwise limit the scope of the aspects and implementations in any way. Indeed, for the sake of brevity, conventional manufacturing, connection, preparation, and other functional aspects of the system may not be described in detail. Furthermore, the connecting lines shown in the various FIGURES are intended to represent exemplary functional relationships and/or physical couplings between the various elements. Many alternative or additional functional relationship or physical connections may be present in the practical system, and/or may be absent in some embodiments.

It is to be understood that the configurations and/or approaches described herein are exemplary in nature, and that these specific embodiments or examples are not to be considered in a limiting sense, because numerous variations are possible. The specific routines or methods described herein may represent one or more of any number of processing strategies. Thus, the various acts illustrated may be performed in the sequence illustrated, in other sequences, or omitted in some cases.

The subject matter of the present disclosure includes all novel and nonobvious combinations and sub-combinations of the various processes, systems, and configurations, and other features, functions, acts, and/or properties disclosed herein, as well as any and all equivalents thereof.

1. A vapor phase precursor delivery system comprising:
a gas inlet;
a gas outlet;
a vessel constructed and arranged for storing a precursor; and,
a connecting tube contained within the vessel, the connecting tube being connected to and in fluid communication with the gas inlet, wherein the system is provided with a moveable injector connected to and in fluid communication with the connecting tube and constructed and arranged for injecting gas from the gas inlet at a substantial constant level from a surface of the precursor in the vessel.

2. The system according to claim 1, wherein the system is provided with a fill port for filling the vessel with a precursor.

3. The system according to claim 1, wherein the connecting tube is constructed and arranged flexibly to allow for movement of the injector with respect to the gas inlet.

4. The system according to claim 1, wherein the vessel is constructed and arranged to hold a liquid precursor.

5. The system according to claim 4, wherein the system is provided with a floating body constructed and arranged for floating on the liquid precursor and for supporting the injector.

6. The system according to claim 5, wherein the floating body and the injector are constructed and arranged to provide a gas flow over the surface of the precursor.

7. The system according to claim 5, wherein the floating body and the injector are constructed and arranges to provide a gas flow underneath the surface of the precursor.

8. The system according to claim 5, wherein the floating body and the injector are constructed and arranged to create bubbles underneath the surface of the precursor.

9. The system according to claim 1, wherein the injector is constructed and arranged as a showerhead provided with multiple holes for injecting gas from the holes at a substantial constant level from the surface of the precursor.

10. The system according to claim 1, wherein the system is provided with multiple injectors for injecting gas from the gas inlet at a substantial constant level from the surface of the precursor.

11. The system according to claim 1, wherein the system is provided with a lifting device constructed and arranged for moving and supporting the injector and the system is provided with a controller to control the movement of the injector by the lifting device.

12. The system according to claim 11, wherein the system is provided with a level measurement device to measure a level of the precursor and the controller is operably connected to the level measurement device to control the movement of the injector based on the precursor level measured by the level measurement device.

13. The system according to claim 12, wherein the controller is programmed to control the lifting device to have the injector to provide a gas flow over the surface of the precursor.

14. The system according to claim 12, wherein the controller is programmed to control the lifting device to have the injector to provide a gas flow underneath the surface of the precursor.

15. The system according to claim 12, wherein the vessel is constructed and arranged to hold a liquid precursor and the controller is programmed to control the lifting device to have the injector to create bubbles underneath the surface of the precursor.

16. The system according to claim 1, wherein the vessel is constructed and arranged to hold a solid precursor.

17. The system according to claim 16, wherein the injector is constructed and arranged to be supported on the surface of the solid precursor in the vessel and is constructed and arranged to follow the surface of the solid precursor when the solid precursor sublimates from the vessel.

18. The system according to claim 1, wherein the vessel is constructed and arranged to hold and sublimate a metal chloride.

19. The system according to claim 18, wherein the vessel is constructed and arranged to hold and sublimate hafnium chloride or zirconium chloride as the metal chloride.

20. The system according to claim 1, constructed and arranged to hold and evaporate a liquid with a relatively high viscosity compared to a viscosity of water.

21. The system according to claim 2, wherein the system is provided with a lid to cover the fill port.

22. A vapor phase deposition apparatus comprising a vapor phase precursor delivery system according to claim 1 for delivering a vapor phase precursor for depositing a layer on a substrate.

23. The vapor phase deposition apparatus according to claim 22, wherein the apparatus is a vertical furnace comprising a reactor constructed and arranged to load a boat with a plurality of substrates and the vapor phase precursor delivery system is constructed and arranged for delivering a vapor phase precursor for depositing a layer on the substrate in the reactor.
